(19) United States
(12) Patent Application Publication
(10) Pub. No.: US 2011/0095919 A1
(43) Pub. Date: Apr. 28, 2011

(54) KEYBOARD HAVING CAPACITANCE-SENSITIVE KEY FIELDS

(75) Inventors: Michael Ostermöller, Bad Hersfeld (DE); Thomas Wahl, Fulda (DE); Ottmar Möller, Fulda (DE)

(73) Assignee: Hypercom GmbH, Bad Hersfeld (DE)

(21) Appl. No.: 12/735,806

(22) PCT Filed: Jan. 26, 2009
(86) PCT No.: PCT/EP2009/050855

§ 371 Date: Dec. 13, 2010

(30) Foreign Application Priority Data
Feb. 20, 2008 (DE) 10 2008 009 936.8

(51) Int. Cl. H03K 17/955

(52) U.S. Cl. 341/33

(57) ABSTRACT

A keyboard having a plurality of key fields and a plurality of capacitive elements, which are associated with the key fields, and measuring electronics is proposed. The measuring electronics are implemented for the purpose of detecting a change of the capacitance value of one of the capacitive elements between a non-actuation level, which is in a first capacitance value range, and an actuation level, which is in a second capacitance value range, and then outputting an actuation signal. The measuring electronics are also implemented to detect a change of the capacitance value of the non-actuation level and a manipulation level above the second capacitance value range and to then output an alarm signal. The attempt to manipulate the keyboard can thus be detected on the basis of the capacitance value increase associated therewith.

### FIELD OF THE INVENTION

The present invention relates to a keyboard having capacitance-sensitive key fields.

### BACKGROUND OF THE INVENTION

Keyboards can be used, for example, as an interface between a person and a machine. In this context, data can be input to the machine with the aid of the keyboard. If such input data, for example, comprises security-relevant data which must not be intercepted or modified by unauthorised third parties, the keyboard should be protected from possible tampering by third parties. Such keyboards protected against tampering can be advantageous, for example, for so-called payment terminals at which, for example, a PIN (Personal Identification Number) to be kept secret can be entered by means of the keyboard.

Conventional keyboards typically comprise a circuit board having electrically conducting contact areas provided on the surface thereof. The contact areas usually consist of respectively two adjacently disposed contact halves. Above the circuit board there is usually provided a switching element at which an electrically conducting element is provided on a surface directed towards the circuit board, for example, in the form of a carbon pill or a metal plate. If a key formed in such a pressure-sensitive mat is actuated, the electrically conductive element short circuits the two contact halves disposed on the circuit board. Such a bridging of the two contact halves can be detected with the aid of evaluation electronics, e.g. a microcontroller. In a conventional keyboard, usually a plurality of pairs of contact halves are interconnected to a microcontroller in a matrix-like manner in order to reduce the number of necessary lines.

A potential attack on such a conventional keyboard in order to intercept or tamper with data input with the aid of the keyboard could involve electrically contacting the contact halves associated with a key from outside so that an actuation of the key could be detected by an external attacker. Instead of tapping individual keys, the entire keyboard could also be intercepted by connecting an evaluation circuit to the keyboard matrix. This can be easily possible particularly in view of exposed, electrically contactable contact halves.

In addition, conventional keyboards are known in which capacitive elements are provided instead of electrically bridgeable contact halves. In this case, a capacitive element is associated with each key field of the keyboard. The capacitance or the capacitance value of a capacitive element varies according to whether the key field is actuated or not. Measuring electronics connected to the capacitive elements can thus detect whether a key field has been actuated on the basis of a varying capacitance value of a capacitive element.

However, it has been found that even such keyboards provided with capacitance-sensitive key fields can be tampered with.

There is therefore a need for a keyboard in which intercepting or tampering with input data is at least made difficult.

### SUMMARY OF THE INVENTION

This need can be met by the subject matter of the present invention according to the independent claim. Embodiments of the present invention are described inter alia in the dependent claims.

According to a first aspect of the present invention, a keyboard is described, comprising a plurality of key fields, a plurality of capacitive elements and measuring electronics. Each capacitive element is associated with a key field and is designed to change its capacitance value when actuating the key field associated with said element. The measuring electronics are configured to measure the capacitance value of each of the capacitive elements. The measuring electronics are thereby configured to detect a change of the capacitance value of one of the capacitive elements between a non-actuation level lying in a first capacitance value range and an actuation level lying in a second capacitance value range and then, as a result, output an actuation signal. The measuring electronics are further configured to detect a change of the capacitance value of the one capacitive element between the non-actuation level lying in the first capacitance value range and a manipulation level lying above the second capacitance value range and then, as a result, output an alarm signal.

In other words, the present invention can be considered to be based on the following idea: a keyboard provided with a plurality of capacitive elements is, with the aid of its measuring electronics, not only able to distinguish between an actuated state and a non-actuated state of a key or a key field but can furthermore also detect if the capacitance value of a capacitive element increases above an upper limiting value which then causes the measuring electronics to output an alarm signal.

The functional principle of the keyboard according to the invention can be understood as follows: whilst a key field of the keyboard is not actuated, the capacitance value of the capacitive element associated with this key field lies within a first capacitance value range. This capacitance value designated as non-actuation level, does not necessarily need to be a fixed constant value. The non-actuation level can, for example, fluctuate slightly as a result of climatic influences. The first capacitance value range can in this case be selected so that the capacitance value of a capacitive element always remains within the first capacitance range despite such predictable fluctuations in normal operation of the keyboard as long as the relevant key or the relevant key field is not specifically actuated.

If a key field is actuated, for example, by direct manual contact of the key field by a user or by depressing a key located thereabove, the capacitance value of the associated capacitive element changes as a result of the additional capacitance of the user's finger or the key. The measuring electronics are configured in such a manner that they can detect a change of the capacitance value between the non-actuation level and a corresponding actuation level and can then output an actuation signal as a result. Similarly as the non-actuation level, the actuation level does not need to be a fixed value in this case but can be located within a capacitance value range. Usually, the second capacitance value range in which the actuation level is located will lie above the first capacitance value range in which the non-actuation level is located since the capacitance value of the capacitive element usually increases on actuation.

The actuation signal delivered by the measuring electronics can, for example, be relayed to evaluation electronics which can assign, for example, a specific data value to an actuation signal associated with a specific capacitive element. In this way, a data set such as, for example, a PIN can be input by successive actuation of different key fields of the keyboard.

However, the measuring electronics of the keyboard according to the invention are not only able to detect a change of capacitance value between a non-actuation level and an actuation level. They are also configured to detect a change of the capacitance value of a capacitive element towards a manipulation level lying above the second capacitance value range and to then output an alarm signal. In other words, the second capacitance value range can not only have a lower limit above which the measuring electronics identifies an actuation of the relevant key field but also an upper limit above which the measuring electronics no longer assumes an actuation of the relevant key field but a tampering to the keyboard.

In other words, the measuring electronics can detect if the capacitance value of a capacitive element moves above an upper limiting value up to which correct actuation of the key field can be assumed under normal conditions. In the event of such a too-high capacitance value, the measuring electronics assumes that the keyboard has been tampered with in some way and outputs an alarm signal. This alarm signal can, for example, lead to the generation of an audibly or visually perceptible alarm or can be relayed to a control centre.

In this context, the keyboard according to the invention can utilise the fact that the capacitance value of a capacitive element usually increases when an attempt is made to tamper with the keyboard. For example, this capacitance value increases if a spy electronic system is connected in parallel with a capacitive element or to other electronic components present in the keyboard as part of an attempt at tampering. Also if, as part of an attempt at tampering, a pressure-sensitive film or an additional circuit is disposed above the actual keyboard in order to detect an actuation of key fields and relay this to an unauthorised third party, the capacitance value of the capacitive elements of the keyboard located thereunder usually increases. Even when carrying out the tampering measures, the capacitance value can increase so greatly that it is detected by the measuring electronics as the manipulation level lying above the second capacitance value range. However, if the capacitance value is not increased so strongly that the manipulation level would be reached merely as a result of the tampering attempt, usually at least the next actuation of a key field of a keyboard tampered with in such a manner has the result that the corresponding capacitance value is increased as far as a manipulation level so that at the latest an alarm signal is then output.

Possible features, details and advantages as well as embodiments of the keyboard according to the invention are discussed hereinafter in detail.

The keyboard can have an arbitrary number of key fields. For example, the keyboard can have 10 keys having a numbering “0” to “9” so that an arbitrary numerical code can be input. However, key fields which are allocated letters or other symbols can also be provided.

A key field can, for example, be a two-dimensional area of the keyboard which can be contacted or depressed by a user when he wishes to input the data content associated with the key field.

A capacitive element can be an arbitrary electronic component that has a capacitance value and that can change its capacitance value on approaching other capacitive objects. For example, a capacitive element can be configured as a two-dimensional capacitor which is disposed in the vicinity of an operator interface of the keyboard. If an object made of a suitable, in particular dielectric material approaches the operator interface, the capacitance value of the capacitive element located in its vicinity varies.

The measuring electronics can be an arbitrary circuit which is electrically connected to the capacitive elements and which is also able to measure their respective instantaneous capacitance value. The capacitance value measured by the measuring elements can be recorded and processed in an analogue or digital manner.

The measuring electronics can also be able to detect if the capacitance value of a capacitive element is located in a first capacitance value range and evaluate this to the effect that the associated key field is not actuated at the present time. The non-actuation level lying inside the first capacitance value range is designated as the “baseline”.

The measuring electronics is furthermore able to detect if the capacitance value of the capacitive element changes in such a manner that it is located in a second capacitance value range, whereupon an actuation of the associated key field is assumed.

In this context, the first and the second capacitance value range can be fixedly predefined ranges pre-programmed in the measuring electronics. Alternatively, the capacitance value ranges can be subsequently programmed in selectively by an operator of the keyboard. “Intelligent learning” of the keyboard is possible as another alternative whereby predictable operating conditions under specific ambient conditions are predefined for the keyboard and the keyboard can then learn the capacitance value pertaining to a non-actuated state and an actuated state in each case.

The measuring electronics is additionally able to detect not only whether the measured capacitance is located with the first capacitance value range, the second capacitance value range or outside both capacitance value ranges but in particular whether it is located above the second capacitance value range. In such a case, the measuring electronics assumes that the keyboard has been tampered with since otherwise the capacitance value should not be located in such a high value range. It then outputs an alarm signal.

The measuring electronics can at the same time be set up in such a manner that the alarm signal is only output when a capacitance value above the second capacitance value range is measured over a predetermined or pre-determinable minimum time. In this way, false alarms, for example as a result of short-term fluctuations or short-term static charges can be largely obviated.

The measuring electronics are preferably located inside a casing surrounding or forming the keyboard. In particular, the measuring electronics can be located in a region of the casing protected in a particular manner against access from outside.

According to one embodiment of the present invention, the measuring electronics are further configured to detect a change of the capacitance value of one of the capacitive elements between the non-actuation level lying in the first capacitance value range and an intermediate level lying between the first and the second capacitance value range and then outputting a warning signal if the intermediate level is detected to be longer than predetermined or a pre-determinable duration.

In other words, according to this embodiment, the measuring electronics can not only detect if the capacitance value of a capacitive element is located above an upper limit of the second capacitance value range but also if it is below the lower limiting value of the second capacitance value range, that is, between the first and the second capacitance value range. Such a capacitance value located at an intermediate level can indicate a tampering of the keyboard.

However, since this intermediate range is necessarily passed through on transition between a non-actuation state and an actuation state, the measuring electronics only assumes a probability of a tampering attempt if the capacitance value is located at such an intermediate level for longer than a specific time.

Depending on the area of application, the specific time can be in the range of a few seconds to a few hours. If the measuring electronics detects over such a long time that the capacitance value of a specific capacitive element is neither located at a non-actuation level nor at an actuation level but is located somewhere in between, it outputs a warning signal. This warning signal can, for example, be received by evaluation electronics.

Depending on how sensitively these evaluation electronic are set, it can treat the warning signal similarly to an alarm signal and cause an alarm or it can trigger a graduated version of an alarm, for example, an alarm which can merely be perceived visually. Alternatively, it can wait until the warning signal has been maintained for a specific time and only then trigger an alarm.

According to a further embodiment of the present invention, the key fields are disposed on the surface of the keyboard in such a manner that they can be contacted by hand by an operator wherein a capacitive element associated with a respective key field is disposed and designed in such a manner that its capacitance value changes on contact by hand from the non-actuation level to the actuation level.

In other words, the capacitive element can be disposed directly on or just below a surface of the keyboard. The capacitive element can at the same time lie open towards the outside, i.e. the components forming the capacitive element can also be exposed towards the outside. However, it is preferable if the capacitive element is covered towards the outside by an electrically insulating layer, for example, in the form of a film, a varnish layer or a thin glass plate. When an operator approaches a key field with his finger and ultimately touches it, the capacitive element located thereon or just below changes its capacitance value. The first and the second capacitance value range are in this case selected so that the measuring electronics measure a non-actuation level as long as no contact by the finger takes place and measures an actuation level as soon as contact takes place.

Such a keyboard manages without movable keys. No mechanical actuation, for example, as a result of an exerted pressure is detected but a change of a capacitance value which results from an additional, preferably dielectric medium such as is formed by a human finger, being brought in to the vicinity of the key field and thereby changing the capacitance value of the capacitive element. An additional advantage is that such keyboards can have a flat, easy-to-clean surface.

According to another embodiment of the present invention, an embossed film is associated with a key field.

In one embodiment, an operator of the keyboard can be given a tactile acknowledgement relating to the actuation of a key field. The embossed film can be configured in such a manner that a certain minimum pressure must be exerted thereon so that it snaps from a non-actuated configuration into an actuated configuration. In the non-actuated configuration, the embossed film can hold the finger of the operator at a distance from the capacitive element in such a manner that its capacitance value is barely influenced and the measuring electronics thus assumes a non-actuated state. Only when the embossed film is snapped into the actuated configuration as a result of the finger pressure, does the finger or a dielectric element arrive at the surface of the film directed towards the capacitive element in the vicinity of the capacitive element so that the measured capacitance value is accordingly increased and the measuring electronics can assume an actuation state.

In addition to the tactile acknowledgement, the embossed film also make it possible for the transition from the non-actuated configuration to the actuated configuration to take place very rapidly, for example, in the region of milliseconds, so that the time during which the measured capacitance value in the normal state of the keyboard is located in a value range between the first and the second capacitance value range is correspondingly short. If a corresponding intermediate level persists over a longer time in this embodiment of the keyboard, a tampering with the keyboard can be assumed.

According to a further embodiment of the present invention, a key capable of being shifted between a non-actuated and an actuated position is associated with each key field. In this case, the key has a capacitance-changing element. The key and the capacitive element associated therewith are disposed and designed in such a manner that when the key is shifted from the non-actuated to the actuated position, the capacitance value of the capacitive element changes from the non-actuation level to the actuation level.

In this embodiment, an operator can also be given a tactile acknowledgement relating to the actuation of a key. In this embodiment the keyboard has advantages and properties similar to the embodiment of the keyboard with the embossed film described above. An additional advantage with this embodiment can lie in that the keyboard fitted with movable keys can have similar operating properties to those of conventional keyboards. On the one hand, an operator does not need to change his operating habits, on the other hand an attacker cannot identify from the outside in advance that this is not a conventional keyboard with contacts which are electrically bridgeable by mechanical actuation, but a keyboard according to the invention with capacitive detection of any actuation of the keys.

According to another embodiment, the keys are disposed in a pressure-sensitive mat.

In this embodiment, the keyboard even more strongly resembles a conventional keyboard. In extreme cases, it can even be sufficient to replace the electrically conductive carbon pills or metal plates provided on the underside of the keys of a conventional keyboard by dielectric elements. The mutually opposing contact halves of a conventional keyboard are then no longer short-circuit by depressing the key. Since, however, the two contact halves form a type of capacitor, the capacitance value of the capacitive element produced by the two contact halves changes. In order to convert the conventional keyboard into a keyboard according to the invention, the measuring electronics connected to the contact halves then merely needs to be reconfigured.

According to another embodiment of the present invention, a capacitive element is covered towards an exterior of the keyboard by an electrically insulating layer. As a result, the corresponding capacitive element is not easily electrically contactable from outside. The electrically insulating layer can, for example, be a varnish or a film, preferably a self-adhesive film. The electrically insulating layer is preferably opaque so that the capacitive elements located thereunder cannot be seen from outside.

According to another embodiment of the present invention, one of the capacitive elements is accommodated in the interior of a circuit board.

By integrating the capacitive element into the circuit board, this can be better protected from damage and specific tampering from outside.

According to another embodiment of the present invention, the keyboard further comprises a capacitive element serving as a reference sensor that is not associated with a key field.

Such a capacitive element serving as a reference sensor can be constructed in a manner similar to the capacitive elements associated with the key fields. It can therefore exhibit similar electrical behaviour to the latter although it is not associated with a key field. This lack of association can be achieved by this additional capacitive element not being identifiable from outside as a key field. Alternatively, the additional capacitive element can be specifically protected from any actuation, for example, by contact from outside.

The capacitive element serving as a reference sensor can, for example, be used when defining the first capacitance value range. Its capacitance value can be defined as non-actuation level for the capacitive elements associated with the key fields. Since its capacitance value changes similarly to that of the other capacitive elements as a result of humidity fluctuations, temperature fluctuations etc., the non-actuation level or the “baseline” is continuously tracked to the prevailing climatic influences.

According to another embodiment, the measuring electronics are designed to measure the capacitance value of each capacitive element cyclically.

In other words, the individual capacitive elements can be successively measured one after the other. In this case, a measurement sequence can be static or varied temporally in a predetermined or, alternatively, random manner. Should an attacker succeed in discovering the measured capacitance values accessible to the measuring electronics, he nevertheless does not yet know which of the capacitive elements associated with the different key fields the measuring electronics are instantaneously measuring, so that discovering the data input via the keyboard is made additionally difficult.

According to another embodiment, the measuring electronics of the keyboard is programmable.

Such programmable measuring electronics can be implemented, for example, in the form of a PSoC© microcontroller (Programmable System-on-Chip), which in addition to a microcontroller core with flash and SRAM, additionally has analogue and digital arrays which can be configured by the user and is supplied, for example, by the company Cypress. Various applications can be achieved with these arrays. The configuration of the hardware can even be switched during the running time to another configuration stored in the memory.

The limiting values of the first and second capacitance value range can be programmed, for example, in the measuring electronics. In addition, time thresholds can be programmed, which must be adhered to so that the measuring electronics, for example, detects an actuation level, manipulation level or intermediate level. Furthermore specific tolerance ranges can be programmed in. In addition, the sequence of a successive measurement process can be programmed in. Optionally, a sensitivity of each capacitive element can be individually set so that, for example, an “on” switch requires a longer actuation than a normal key field. In addition, various evaluation methods can be implemented in the measuring electronics and if necessary, the determined data can even be encrypted. In order to allow subsequent adaptation of the keyboard to different applications, the measuring electronics can be reconfigured by means of suitable firmware. The programmability of the measuring electronics also allows a low external wiring expenditure with a short development time at the same time.

It is noted that the features described above in connection with various exemplary embodiments can be arbitrarily combined with one another.

Further features and advantages of the present invention will become apparent to the person skilled in the art from the following description of exemplary embodiments which, however, should not be interpreted as restricting the invention, with reference to the accompanying drawings.

### DESCRIPTION OF THE FIGURES

FIG. 1 shows a keyboard according to a first embodiment of the present invention.

FIG. 2 shows as an example the behaviour of the capacitance value of a capacitive element in various operating states of the keyboard.

FIG. 3 shows another embodiment of a keyboard according to the invention.

FIG. 4 shows yet another embodiment of a keyboard according to the invention.

All the figures are merely schematic diagrams. In particular, distances and size relationships are not reproduced true to scale in the figures. In different figures, the same or identical elements are provided with the same reference numbers.

### DETAILED DESCRIPTION OF EMBODIMENTS OF THE INVENTION

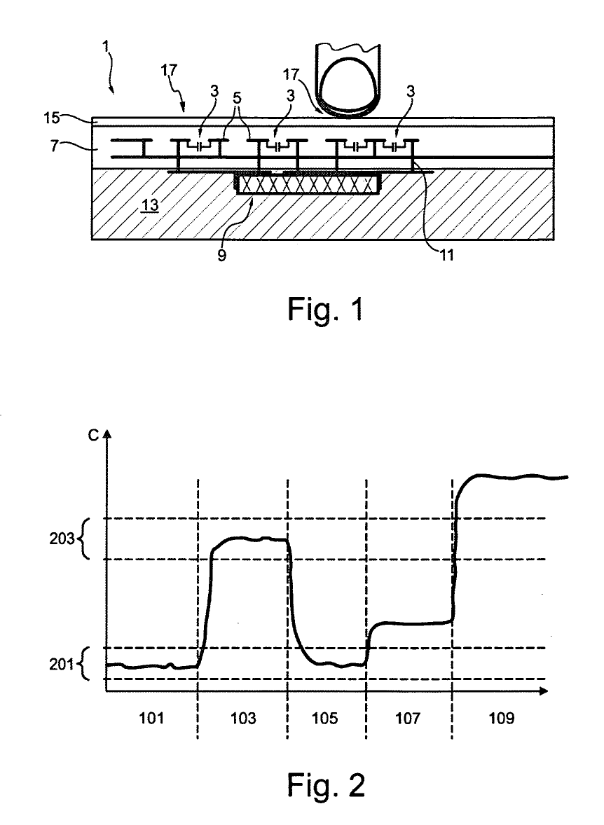

FIG. 1 shows in cross-section a keyboard 1 according to the invention in which capacitive elements 3 formed by two-dimensional metal layers 5 disposed parallel to the surface of the keyboard 1 are formed inside the circuit board 7. Located on the underside of the circuit board 7 are measuring electronics 9 which are connected to the metal layers 5 forming the capacitive elements 3 by buried vias 11.

The measuring electronics 9 are designed to measure the capacitance value of the individual capacitive elements 3 or a change of the capacitance value and depending on the measured capacitance value, to output either an actuation signal, an alarm signal, a warning signal or a non-actuation signal.

The measuring electronics 9 are located inside a secured region 13 underneath the circuit board 7 which forms a boundary towards the outside. The measuring electronics 9 can, for example, be encapsulated inside the secured region 13 by means of a resin compound.

A cover film 15 is provided in the outwardly directed surface of the circuit board 7. On this cover film the key fields 17 which can be actuated by the finger of an operator can be visually emphasised by means of printing.

The capacitance value of the capacitive elements 3 can be measured with the aid of the measuring electronics 9 in various ways, for example, by means of a capacitance-to-digital converter. In principle, all the key fields 17 or their associated capacitive elements 3 are successively interrogated individually and, following an interrogation cycle, the result is provided to an evaluation circuit (not shown).

The measuring electronics 9 can be implemented by means of a PSoC microcontroller such as is distributed for example, by Cypress Semiconductor as a so-called CapSense module and which provides a capacitance measuring interface. Here a special PSoC series with additional analogue multiplexer can be selected to increase the number of possible measurement channels (key fields). In addition, the digital interface is selected to transfer the key codes to the evaluation circuit. An I²C bus, a UART (transmit only) or also port pins which are controlled by software are available. An interrupt output should possibly be added to rapidly signal actuated keys. Finally, the software modules for capacitance measurement and data transmission are configured and the firmware created for the entire function.

FIG. 2 shows the capacitance value C measured by the measuring electronics 9 in various operating states of the keyboard 1.

During a first non-actuation state 101 in which the finger of an operator does not come into the vicinity of the surface of the keyboard in the area of the key field which has just been read out, the measured capacitance value C lies within a first capacitance value range 201. As a result of environmental influences, the capacitance value can slightly vary within the upper and lower limit of the first capacitance value range 201.

If a user touches a key field 17 with his finger, in an actuation state 103 the measured capacitance value C increases to an actuation level lying within a second capacitance value range 203 as a result of the additional capacitance caused by the finger. The measured capacitance value of the actuation level can vary within the second capacitance value range 203 as a result of various influences such as, for example, the size of the finger, the perspiration of the hand, the contact pressure and related to this, the contact area, etc.

If the finger is moved away from the keyboard again, the capacitance value C returns to the non-actuation level, initially possibly with a slight hysteresis, see Step 105.

In an attempt to tamper with the keyboard, for example, by contacting the metal areas 5 forming the capacitive elements 3, an additional capacitance is produced. Alternatively, a tampering attempt can consist in providing an additional pressure sensitive film above the cover film 15, which is connected to evaluating electronics, which allows an attacker to identify which of the key fields has just been actuated. As shown in Step 107, the capacitance value C measured by the measuring electronics 9 therefore increases above the upper limit of the first capacitance value range 201. In this case, the capacitance value C can lie permanently within a range between the first and the second capacitance value range, which can be interpreted by the measuring electronics as a sign of tampering, whereupon this can deliver a warning signal.

Alternatively, as shown in Step 109, the capacitance value C measured by the measuring electronics 9 can increase above the upper limit of the second capacitance value range 203 merely as a result of the tampering attempt or at the latest on actuation of a key field of the manipulated keyboard. This clearly signals to the measuring electronics 9 that the keyboard has been manipulated since such high capacitance values C cannot be present without any manipulation. The measuring electronics 9 therefore outputs an alarm signal which can result in the generation of an audibly or visually perceptible alarm, a transmission of an appropriate signal to a control centre or the complete decommision of the keyboard.

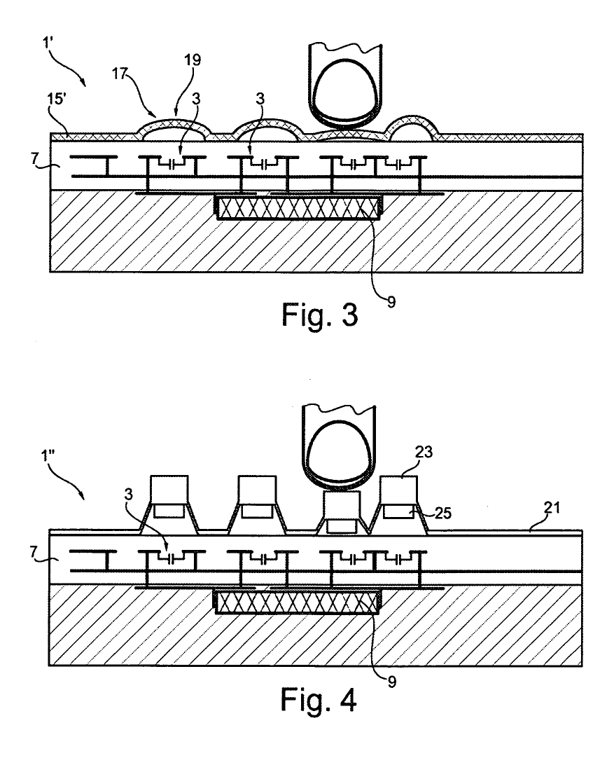

FIG. 3 shows another embodiment of a keyboard 1′ configured according to the invention. In this case embossed regions 19 in which the cover film 15′ is curved upwards and at a distance from the surface of the circuit board 7 are located in the cover film 15′ in the areas of the key fields 17. On actuating a key field 17, a certain minimum pressure must be exerted by the finger of a user on the embossed film 15′ before this snaps downwards. Due to the snapping the finger suddenly comes closer to the capacitive element 3 located thereunder and in this way increases the capacitance value measured there.

In the embodiment of the keyboard 1″ according to the invention shown in FIG. 4, the cover film was replaced by a pressure sensitive mat 21. Keys 23 are formed integrally with the pressure sensitive mat and capacitance-value changing elements 25 in the form of dielectric plates are disposed on their lower surface directed toward the surface of the circuit board 7.

As long as the keys 23 are not depressed, the capacitance-value changing elements 25 are so far spaced from the capacitive elements 3 located thereunder that they barely influence their capacitance value. When a key 23 is depressed by a user, a corresponding capacitance-value changing element 25 comes into the vicinity of or directly onto the surface of the circuit board 7 and therefore in the vicinity of the capacitive element 3 integrated therein and changes its capacitance value so strongly that it comes within the second capacitance value range 203 and is thus detected as an actuation level.

In the embodiments of the keyboard according to the invention described above, the following advantages are obtained in particular:
in the capacitive measuring method no direct tracing of the keys or key fields is possible;
the capacitive elements acting as sensor surfaces can be laid in an inner layer of the circuit board so that in a tampering attempt, key pads located thereover must first be milled off;
furthermore, any additionally connected line and subsequent electronics constitutes another capacitive load connected in parallel which can be detected by the measuring electronics. Here, for example, it is possible to respond to the main controller serving as an evaluation circuit by means of a silent alarm;
due to the flexible structure of the PSoC, a flexible response can be made to further requirements. Thus, the sequence of the key interrogation can be permanently changed in a cycle or the transmission to a main controller can be used in a proprietary manner. During operation of the keyboard, the base level of the capacitive element can be adapted in order to take account of effects such as temperature and air humidity. For this purpose and also for identifying tampering, an additional capacitive element serving as a reference without a key function can be appropriate. In addition, the switching threshold and hysteresis can be individually set for each individual key field;
it is furthermore feasible to shift the evaluation module or the measuring electronics into the circuit board itself and thus render difficult or prevent any attack on the chip itself.

Compared with conventional keyboards with contact areas, the capacitive keyboard according to the invention can furthermore have the following advantages:
connection of an evaluation circuit without influencing the functionality of the keyboard is almost impossible;
it is possible to achieve keyboards having a smooth surface which is easy to clean;
dust and dirt have scarcely any influence on the functionality of the keyboard;
the contact areas of the key field exhibit no wear effects.

In particular if the measuring electronics is designed to be programmable, the following advantages can be further achieved:
a low external circuitry expenditure is obtained;
short development times can be achieved;
calibration by means of firmware is possible;
a flexible and programmable data communication with a main controller is possible, and possibly with data concealment or data encryption;
it is possible to adapt to varying ambient conditions such as, for example, temperature, humidity etc. during operation of the firmware;
a number of key fields and a sequence for their interrogation can be configured; a sensitivity can be set individually for each sensor;
different evaluation methods can be implemented and a configuration of the hardware can be changed during the running time.
Component tolerances can be compensated by means of the firmware.

Further embodiments such as are possible as a result of the capacitance-sensitive key fields can also be integrated in the keyboard according to the invention.

For example, the key fields can be configured as slide controls in order that, for example, contrast, loudness or brightness values can be continuously adjusted. The capacitive elements can be formed using transparent conductors such as, for example, ITO (Indium Tin Oxide) so that a screen, for example, in the form of LCDs can be arranged behind the capacitive elements and the keyboard can be configured in the form of touch-pads.

Finally it is noted that expressions such as “comprising” or similar should not exclude further elements or steps from being provided. Furthermore, it is pointed out that “one” or “a” does not exclude a plurality. In addition, features described in conjunction with the various embodiments can be arbitrarily combined. It is further noted that the reference numbers in the claims should not be interpreted as restricting the scope of the claims.

### REFERENCE LIST

1 Keyboard
3 Capacitive element
5 Metal layer
7 Circuit board
9 Measuring electronics
11 Buried via
13 Secured region
15 Cover film
15′ Embossed cover film
17 Key field
19 Embossed regions
21 Pressure-sensitive mat
23 Key
25 Capacitance value changing element
101 Non-actuation state
103 Actuation state
105 Non-actuation state
107 Manipulation state
109 Manipulation state
201 First capacitance value range
203 Second capacitance value range

1. A keyboard, comprising:
a plurality of key fields;
a plurality of capacitive elements, wherein each capacitive element is associated with a key field and wherein each capacitive element is designed to change its capacitance value when actuating the key field associated with said element;
measuring electronics which are configured to measure the capacitance value of each of the capacitive elements;
wherein the measuring electronics are configured to detect a change of the capacitance value of one of the capacitive elements between a non-actuation level lying in a first capacitance value range and an actuation level lying in a second capacitance value range and then output an actuation signal in response thereto;
wherein the measuring electronics are further configured to detect a change of the capacitance value of the one capacitive element between the non-actuation level lying in the first capacitance value range and a manipulation level lying above the second capacitance value range and then output an alarm signal in response thereto.

2. The keyboard according to claim 1,
wherein the measuring electronics are further configured to detect a change of the capacitance value of the one capacitive element between the non-actuation level lying in the first capacitance value range and an intermediate level lying between the first and the second capacitance value range and then output a warning signal if the intermediate level is detected for longer than a pre-determinable duration.

3. The keyboard according to claim 1,
wherein the key fields are disposed on a surface of the keyboard in such a manner that they can be contacted by hand by an operator and wherein a capacitive element associated with a respective key field is disposed and designed in such a manner that its capacitance value changes on contact by hand from the non-actuation level to the actuation level.

4. The keyboard according to claim 3,
wherein an embossed film (15′) is associated with a key field.

5. The keyboard according to claim 1,
wherein a key capable of being shifted between a non-actuated and an actuated position is associated with each key field, wherein the key has a capacitance value changing element and wherein the key and the capacitive element associated therewith is disposed and designed in such a manner that when the key is shifted from the non-actuated to the actuated position, the capacitance value of the capacitive element changes from the non-actuation level to the actuation level.

6. The keyboard according to claim 5,
wherein the keys are disposed in a pressure-sensitive mat.

7. The keyboard according to claim 1,
wherein a capacitive element is covered towards an exterior of the keyboard by an electrically insulating layer.

8. The keyboard according to claim 1,
wherein a capacitive element is accommodated in the interior of a circuit board.

9. The keyboard according to claim 1,
further comprising a capacitive element serving as a reference sensor that is not associated with a key field.

10. The keyboard according to claim 1,
wherein the measuring electronics are designed to measure the capacitance value of each capacitive element cyclically.

11. The keyboard according to claim 1,
wherein the measuring electronics are programmable.
